(19) United States
(12) Patent Application Publication
(10) Pub. No.: US 2015/0289381 A1
(43) Pub. Date: Oct. 8, 2015

(54) Method for producing a three-dimensional circuit configuration and circuit configuration

(71) Applicant: Robert Bosch GmbH, Stuttgart (DE)

(72) Inventors: Peter DIESEL, Bad Hindelang (DE); Martin Winkler, Sonthofen (DE); Robert Hengler, Durach (DE); Michael Schlitzkus, Dietmannsried (DE)

(21) Appl. No.: 14/666,474

(22) Filed: Mar. 24, 2015

(30) Foreign Application Priority Data
Apr. 4, 2014 (DE) 10 2014 206 565.8

(51) Int. Cl. H05K 3/10; H05K 1/11; H05K 1/18; H05K 1/02; H05K 1/09

(52) U.S. Cl. CPC H05K 3/101; H05K 1/0284; H05K 1/092; H05K 1/182; H05K 1/11

(57) ABSTRACT

A method for producing a three-dimensional, injection-molded circuit configuration includes: providing at least two injection molds, in each case having at least one effective surface; applying an electrically conductive material on at least one of the effective surfaces of at least one of the injection molds, while forming electrically conductive patterns; forming a hollow space bounded by the effective surfaces of the at least two injection molds; introducing an insulating material into the hollow space using an injection molding process, and forming a circuit substrate completely or partially accommodating the conductive patterns; and removing from the injection molds the injection-molded circuit configuration having the conductive patterns and the circuit substrate.

### BACKGROUND OF THE INVENTION

1. Field of the Invention

The present invention relates to a method for producing a three-dimensional circuit configuration, particularly an injection-molded circuit configuration, as well as a circuit configuration able to be produced by it.

2. Description of the Related Art

Spatially expanded, three-dimensional, injection-molded circuit configurations, what are referred to as MID circuit configurations (Molded Interconnect Devices, MID), are generally produced in several steps. First of all, a circuit substrate, e.g., having several steps or depressions, is produced in an injection molding process. Subsequently, electrically conductive patterns, which later are used as conductor tracks, or interfacing structures or contact structures, are applied on the surfaces of the circuit substrate. For example, individual component parts are able to be connected electrically to each other via these structures.

To that end, the PCK (printed circuit board Kollmorgen) and SKW (Sankyo Kasei Wiring board) injection molding processes have been produced, in which a layer able to be metallized and a layer not able to be metallized are combined with each other in such a way that the layer able to be metallized forms the desired conductor-track pattern on the surface of the circuit substrate. Subsequently, a metallization is applied on the surface of the entire circuit substrate, the metallization remaining stuck, however, only on the layer able to be metallized. Depending on the shape, it forms a conductor-track pattern, for example, on the surface.

In addition, surface treatment of a circuit substrate, e.g., of a printed circuit board (PCB) is familiar. For example, the circuit substrate may be patterned using a laser.

Furthermore, embossing methods are known in which, for instance, an electrically conductive film is placed on the surface of the circuit substrate and is pressed by the embossing punch at the appropriate locations into the surface of the circuit substrate. Likewise familiar is the application of electrically conductive patterns on the surface of the circuit substrate by deposition, e.g., by the vapor deposition of electrically conductive materials at the appropriate locations.

In general, methods of this type allow only relatively specific formations of circuit configurations and are sometimes costly.

### BRIEF SUMMARY OF THE INVENTION

According to the present invention, a method is provided for producing a three-dimensional injection-molded circuit configuration, that with relatively low expenditure, permits the formation of different electrically conductive patterns on a spatially expanded circuit substrate. In addition, a corresponding injection-molded circuit configuration is provided.

For example, a surface of the circuit substrate may have a plurality of steps or depressions, the electrically conductive patterns also being able to at least partially follow this height profile. Depending on the practical application, the electrically conductive patterns may also project from the surface of the circuit substrate or be situated below the surface. For instance, they form a conductor-track pattern made up of a plurality of conductor-track segments, via which in addition one or more components disposed on the circuit substrate are able to be controlled. The conductor-track segments may also run through the circuit substrate, e.g., from an upper side to a lower side.

The circuit substrate is produced in an injection molding process, in doing which, according to the invention, the electrically conductive patterns are already introduced or integrated into the circuit substrate when producing it, a preferably material-locking or chemical union being able to be formed between the circuit substrate and the electrically conductive patterns.

Thus, several advantages are already achieved according to the present invention:

Because a material-locking or chemical union is provided, release of the electrically conductive patterns from the circuit substrate in response to a strong stress, e.g., in response to vibrations, may be avoided; the conductive patterns are thus enclosed permanently in the circuit substrate. In this manner, an additional electroplating process, in which the electrically conductive patterns are joined with material locking to the circuit substrate may also be omitted.

In particular, this is accomplished, for example, by using a polymer having metallic particles trapped in it, e.g., a silver conductive paste or a soldering paste, as electrically conductive pattern. The material-locking union may then be formed during the injection molding between the polymer of the electrically conductive patterns and the insulating material, preferably plastic, of the circuit substrate injected in the injection molding process. In addition, given a suitably selected material, an at least partial chemical union may also come about between the plastic and the polymer, as they react chemically to one another.

To form the electrically conductive patterns, first of all, at least two injection molds are provided which are able to be joined together and which, after being joined, enclose a hollow space between them. To produce more complex patterns, more than two injection molds may also be used which, having been suitably assembled, then likewise define a hollow space; the hollow space is thus bounded by the surfaces or effective surfaces of the injection molds, these quasi forming the “negative” of the injection-molded circuit configuration to be produced made of the circuit substrate and the conductive patterns. In this context, only the areas of the surfaces of the injection molds which delimit the hollow space are referred to as effective surfaces. The effective surfaces may be formed in nearly any way desired, for example, they may be curved or have several steps.

The electrically conductive pattern is applied in the form of a preferably viscous or pasty electrically conductive material, e.g., a paste having a polymer and conductive, e.g., metallic particles, especially a silver conductive paste or a soldering paste, on the effective surfaces of at least one of the injection molds, conductor-track patterns made up of a plurality of conductor-track segments being “written” or “drawn” using the electrically conductive material. For example, in doing this, the application may be by printing (jetting) or dispensing, the material being fed continuously in the case of imprinting and droplet by droplet in the case of dispensing. However, other application methods are possible as well.

In this state, the electrically conductive material may initially be weakly conductive, since the metallic particles in the polymer have a relatively great distance to each other. If the electrically conductive material is subsequently solidified, for example, by hardening it through heating, in particular, it contracts, which means its volume decreases and the metallic particles are drawn to each other until the majority of the particles touch each other; as a result, the electrically conductive material becomes more conductive.

In this manner, it is possible to achieve the advantage that the layout of the electrically conductive patterns may easily be set in nearly any way desired, since the effective surfaces of the injection molds may be “written” as needed, flexibility being restricted only by the viscosity and the minimum diameter of the hardened, electrically conductive material. Thus, in order to apply a metallization, one is no longer tied to costly 3-D masks to be produced beforehand, and is able to adapt the layout of the electrically conductive patterns quickly to a new practical application. The height and the diameter of the electrically conductive material may also be adjusted, and thus may be varied over different areas.

After the electrically conductive material has solidified or hardened, the injection molds are put together in such a way that the effective surfaces, having the electrically conductive patterns applied on them, form a hollow space. The insulating material, e.g., plastic, is subsequently injected into this hollow space, for instance, via a small opening in one of the injection molds, so that the plastic lies against the effective surfaces and against the electrically conductive patterns, which may also be surrounded at least partially by the plastic. The displaced air in the hollow space is able to escape through additional air outlets. In this context, a material-locking or chemical union may already be formed between the electrically conductive patterns and the filled-in plastic, as the polymer of the paste reacts chemically with the plastic. Consequently, it is helpful if the material used for the electrically conductive patterns is able to enter at least partially into a chemical union with the injection-molded insulating material, or be joined to it with material locking.

When the hollow space is completely filled with plastic, the plastic is hardened and the injection molds are subsequently removed again. In doing this, the electrically conductive patterns are able to release easily from the effective surfaces, since the connection to the plastic is stronger than the connection to the effective surfaces of the injection mold. It is also possible to additionally treat the effective surfaces prior to applying the electrically conductive material, so that the electrically conductive patterns may be released even more easily.

What remains is the injection-molded circuit configuration having the circuit substrate, in which the electrically conductive patterns are incorporated. The surfaces of the electrically conductive patterns and of the injection-molded circuit substrate preferably merge, since both abut directly against the effective surfaces of the injection molds, and the injected plastic is able to flow into interspaces possibly formed.

Consequently, the layout of the electrically conductive patterns on the circuit substrate is advantageously not dependent on an additional treatment or patterning of the prepared circuit substrate, but rather may already be determined beforehand. After the injection molding, the configuration is thus already by and large complete. Only additional electronic or electrical components or electrical connections, e.g., to a load, are able to be joined to the electrically conductive patterns, for which purpose, further interfacing structures, e.g., metal platelets being able to be provided that likewise may already be placed onto the effective surfaces of the injection molds prior to the injection molding and brought into connection with the electrically conductive material. These interfacing structures facilitate the electrical junction, e.g., by soldering or adhesive bonding, with an electric line, for example.

Advantageously, more complex layouts of the electrically conductive patterns are possible as well. For example, a plurality of layers of the electrically conductive material may be applied one upon the other on the effective surfaces, the layers being able to be separated from each other by insulating layers. Thus, it is also possible to produce intersecting conductor tracks in the injection-molded circuit configuration. Moreover, prior to the injection molding, further electrical or electronic components, e.g., resistors or transistors, may also be applied on the effective surfaces and joined to the electrically conductive patterns, so that they are likewise molded in when injecting the plastic. In this manner, these components may advantageously be protected from environmental influences, as well.

### BRIEF DESCRIPTION OF THE DRAWINGS

FIG. 1a and 1b show two injection molds having electrically conductive patterns formed on their effective surfaces.

FIG. 2 shows the effective surface of the injection mold according to FIG. 1a having additional structures.

FIG. 3 shows the injection molds in the assembled state prior to the injection of the plastic.

FIG. 4 shows a finished injection-molded circuit configuration according to a first specific embodiment.

FIG. 5 shows a finished injection-molded circuit configuration according to a second specific embodiment.

FIG. 6 shows a flow chart of the method according to the present invention.

### DETAILED DESCRIPTION OF THE INVENTION

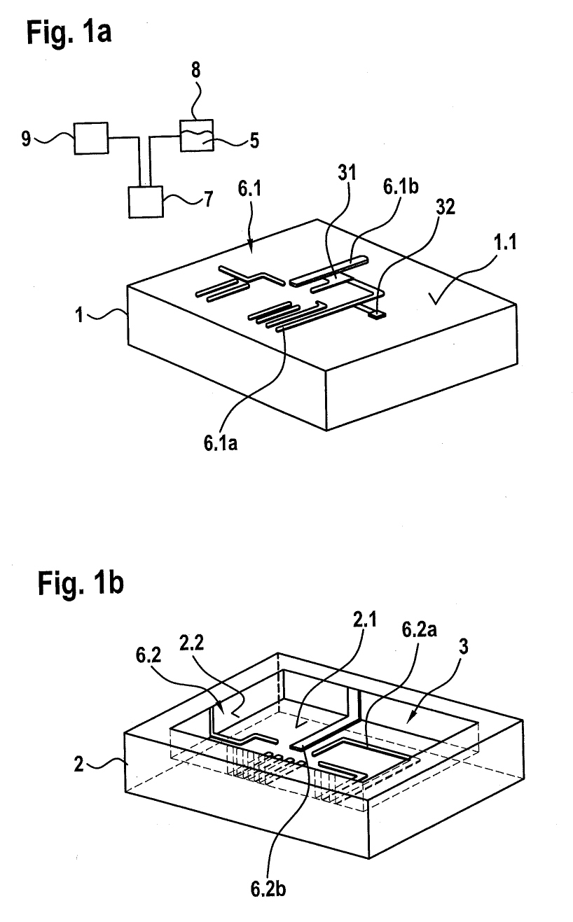

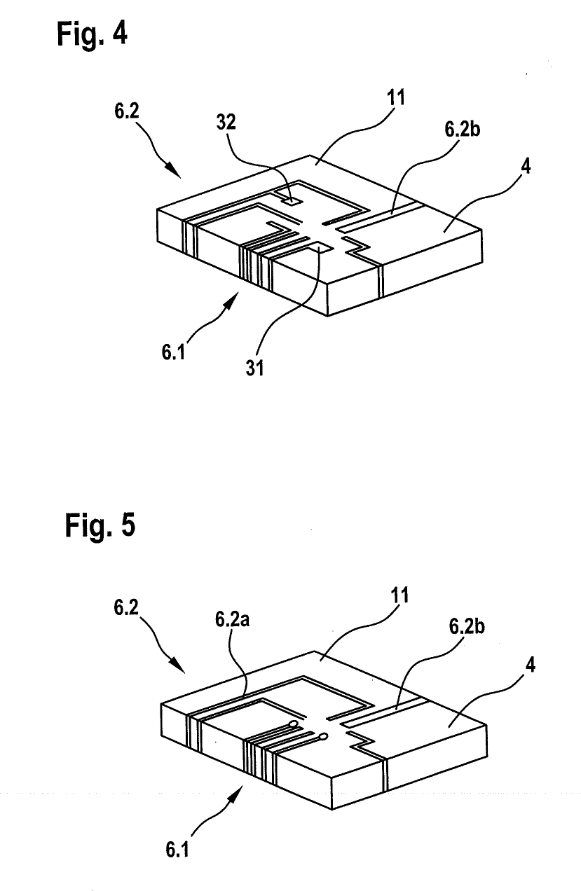

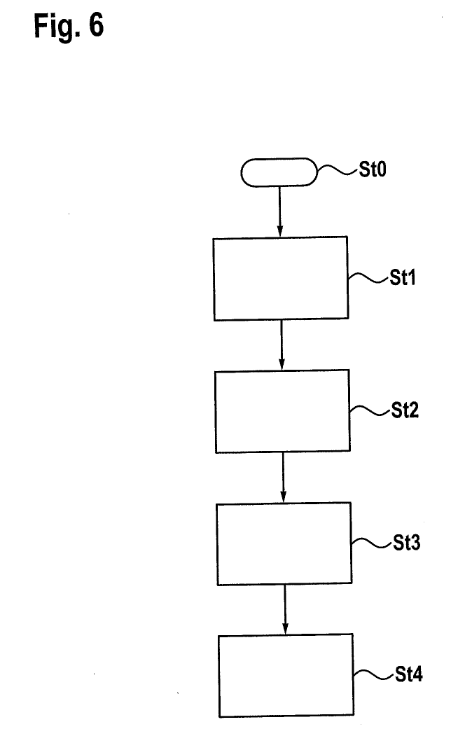

FIGS. 1a and 1b show two injection molds 1, 2, a first injection mold 1 being in the form of a rectangular parallelepiped and a second injection mold 2 taking the form of a rectangular parallelepiped having a depression 3. The edge lengths of the surface areas of both injection molds 1, 2 are more or less identical, so that both injection molds 1, 2 are able to be placed flush one upon the other. Injection molds 1, 2 define with their faces 1.1, 2.1 and lateral surfaces 2.2 realized as effective surfaces, the outer form of injection-molded circuit configuration 4 to be produced, that is, they form the “negative” of injection-molded circuit configuration 4, which is shown in two examples in FIGS. 4 and 5. The two injection molds 1, 2 shown represent only one simple specific embodiment; however, more than two injection molds which, for example, have a plurality of steps and depressions, may also be used in order to obtain a complex, spatially expanded, injection-molded circuit configuration 4.

To produce injection-molded circuit configuration 4 shown in FIGS. 4 and 5, in a first step St1, electrically conductive patterns 6.1, 6.2 are initially applied on injection molds 1, 2. For that purpose, an electrically conductive material 5, e.g., a viscous paste, especially a silver conductive paste or a soldering paste, is applied on injection molds 1, 2. According to FIG. 1a, electrically conductive material 5 is applied on a first face 1.1 of first injection mold 1, and according to FIG. 1b, on a second face 2.1 in depression 3 of second injection mold 2, electrically conductive material 5 also being able to be applied “bent” on lateral surfaces 2.2 of depression 3. Applied material 5 is quasi “written” onto faces 1.1, 2.1 and lateral surfaces 2.2, respectively, in order, for example, to form conductor-track patterns having a plurality of conductor-track segments 6.1a, 6.1b, 6.2a, 6.2b as electrically conductive pattern 6.1, 6.2. However, faces 1.1, 2.1 and lateral surfaces 2.2 are written only in a certain area, the effective surface, in which injection-molded circuit configuration 4 is later formed, as well.

The dimensions of conductor-track patterns 6.1, 6.2 are determined especially by the composition of electrically conductive material 5 as well as by the manner of application. According to FIG. 1a, electrically conductive material 5, which may be made of a polymer, for example, with electrically conductive particles, e.g., silver, trapped in it, is applied preferably from a reservoir 8 via a nozzle 7 onto effective surfaces 1.1, 2.1, 2.2, e.g., by imprinting (jetting) or dispensing. The application may be controlled by a control device 9, for example.

The dimensions of electrically conductive material 5 are therefore a function particularly of the diameter of nozzle 7 as well as the particle size of the polymer, that is, the electrically conductive particles. For example, the diameter is thus on the order of approximately 0.5 mm. After electrically conductive material 5 has been applied, it is solidified, e.g., is hardened by heating, so that the form is essentially retained during the following process steps. In particular, the volume of material 5 may decrease owing to the hardening, which means the electrically conductive particles draw together; the resistance of material 5 falls, that is, it becomes more conductive.

In addition, according to FIG. 1a, electrical and/or electronic components 32 and interfacing structures 31, e.g., contact surfaces, may also be applied on effective surfaces 1.1, 2.1, 2.2, and be joined to conductive patterns 6.1, 6.2.

In a following step St2, the two injection molds 1, 2 are placed flush one upon the other, as shown in FIG. 3. Because of depression 3, in this exemplary embodiment, a hollow space 10 is formed, bounded by face 1.1, lateral surfaces 2.2 and face 2.1.

In a step St3, preferably a viscous insulating material, preferentially plastic, is subsequently injected into this hollow space 10. To that end, provided in one of injection molds 1, 2 is an inlet opening (not shown), through which the plastic may be admitted. In addition, vent openings are provided, from which the air, displaced during the injection, is able to escape from hollow space 10.

The injected plastic lies in hollow space 10 against effective surfaces 1.2, 2.1, 2.2 and also surrounds electrically conductive patterns 6.1, 6.2 applied on them beforehand. Already upon injecting the plastic, it is able to bond integrally or perhaps chemically with the polymer of electrically conductive material 5.

The injected plastic is subsequently hardened, the hardened plastic forming a circuit substrate 11 of injection-molded circuit configuration 4. That is to say, circuit substrate 11 stabilizes and supports electrically conductive patterns 6.1, 6.2 applied on it, and possibly further components, as well. The dimensions, i.e., the form, of circuit substrate 11 are determined by the form of injection molds 1, 2 and may be selected in nearly any way desired, in doing which, circuit substrate 11 should be thick enough that it is also able to be stressed depending on the type of utilization. Consequently, the thickness should lie in the range of a few millimeters, thus ensuring sufficient stability.

After the plastic has hardened, injection molds 1, 2 may be disassembled and prepared for the next injection-molded circuit configuration 4, for example. Upon taking off injection molds 1, 2, because of the material-locking or chemical union with plastic circuit substrate 11, electrically conductive patterns 6.1, 6.2 remain adherent to it. To facilitate the detachment, prior to applying electrically conductive material 5, effective surfaces 1.1, 2.1, 2.2 may also be additionally treated, so that no residue of material 5 remains stuck upon detachment.

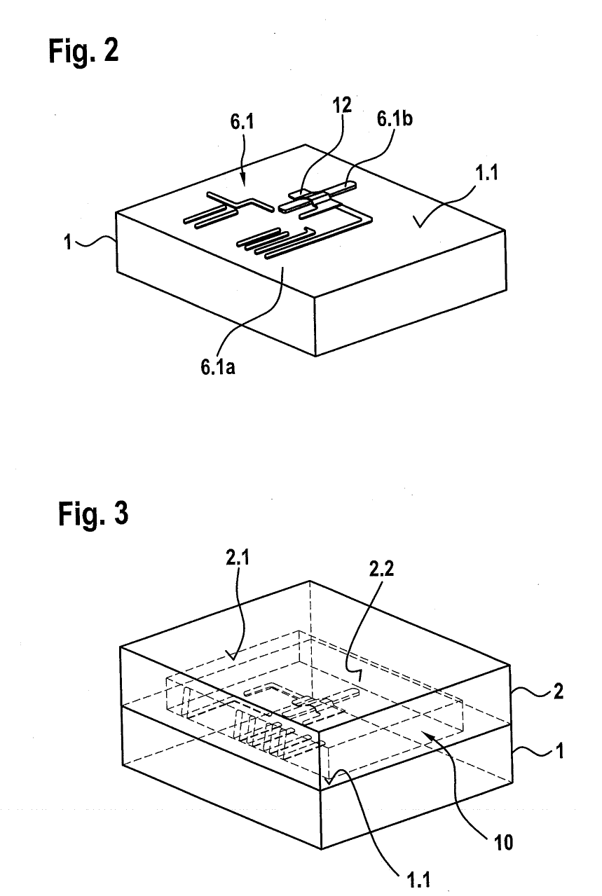

Thus, injection-molded circuit configuration 4 is finished and may be removed in a step St4. According to FIGS. 4 and 5, circuit substrate 11 and electrically conductive patterns 6.1, 6.2 merge directly into one another, thus, form a planar surface. In several areas, electrically conductive patterns 6.1, 6.2 are thicker or form an interfacing structure 31, i.e., a contact surface for lines to a load, for instance, or for further components which may be soldered onto them. Depending on the practical application, superposed patterns are also possible, in which an insulating layer 12 is disposed between two electrically conductive patterns 6.1, 6.2, as shown by way of example in FIG. 2. According to FIG. 4, electrical and/or electronic components 32, e.g., resistors or transistors, may also be disposed in injection-molded circuit configuration 4 and joined to conductive patterns 6.1 6.2. They are at least partially encapsulated at the same time during the injection molding, and therefore are at least partially protected from environmental influences.

However, specific embodiments are also possible in which electrically conductive patterns 6.1, 6.2 project out of circuit substrate 11 or are realized as holes in circuit substrate 11. The shape of injection-molded circuit configuration 4 as a rectangular parallelepiped may likewise vary, depending on the practical application.

What is claimed is:

1. A method for producing a three-dimensional, injection-molded circuit configuration, comprising:
providing at least two injection molds each having at least one effective surface;
applying an electrically conductive material on at least one of the effective surfaces of at least one of the injection molds, while forming at least one electrically conductive pattern;
forming a hollow space bounded by the effective surfaces of the at least two injection molds;
introducing an insulating material into the hollow space using an injection molding process, and forming a circuit substrate at least partially accommodating the at least one electrically conductive pattern; and
removing from the injection molds the injection-molded circuit configuration having the at least one electrically conductive pattern and the circuit substrate.

2. The method as recited in claim 1, wherein the insulating material is hardened after being introduced.

3. The method as recited in claim 2, wherein one of a pasty or viscous electrically-conductive material is applied on at least one of the effective surfaces, and the conductive material is solidified prior to introducing the insulating material into the hollow space.

4. The method as recited in claim 3, wherein a paste having a polymer and conductive particles is used as electrically conductive material.

5. The method as recited in claim 3, wherein the electrically conductive material is applied by one of imprinting or dispensing onto at least one of the effective surfaces.

6. The method as recited in claim 3, wherein in order to form the hollow space, the at least two injection molds are assembled in such a way that their effective surfaces delimit the hollow space.

7. The method as recited in claim 3, wherein the at least one electrically conductive pattern is applied as a conductor-track pattern having a plurality of conductor-track segments.

8. The method as recited in claim 3, wherein the at least one electrically conductive patterns is applied in multiple layers on at least one of the effective surfaces.

9. The method as recited in claim 8, wherein in each case at least one insulating layer is inserted between two adjacent layers.

10. The method as recited in claim 3, wherein prior to introducing the insulating material into the hollow space, at least one of an electrical component and an interfacing structure is applied on at least one of the effective surfaces, the at least one of the electrical component and the interfacing structure being joined electrically to the at least one electrically conductive pattern.

11. An injection-molded circuit configuration, comprising:
a three-dimensional, injection-molded circuit substrate made of an insulating material;
at least one conductive pattern disposed on or in the circuit substrate, wherein the at least one conductive pattern is bonded at least partially by at least one of material locking and chemical bonding to the circuit substrate.

12. The injection-molded circuit configuration as recited in claim 11, wherein the at least one conductive pattern is at least partially made of a hardened, electrically conductive material.

13. The injection-molded circuit configuration as recited in claim 12, wherein the electrically conductive material is a paste having metallic particles.

14. The injection-molded circuit configuration as recited in claim 12, wherein the at least one conductive pattern is molded at least partially into the circuit substrate.

15. The injection-molded circuit configuration as recited in claim 14, wherein in addition to the at least one conductive pattern, at least one of an electrical component and an interfacing structure joined to the at last one conductive pattern is molded into the circuit substrate.
